(19) United States
(12) Patent Application Publication
(10) Pub. No.: US 2025/0219029 A1
(43) Pub. Date: Jul. 3, 2025

(54) INTEGRATED CIRCUIT PACKAGES FOR FACILITATING POWER CONVERTER SYSTEMS AND METHODS

(71) Applicant: Murata Manufacturing Co., Ltd., Kyoto (JP)

(72) Inventor: David M. Giuliano, Bedford, NH (US)

(21) Appl. No.: 18/402,497

(22) Filed: Jan. 2, 2024

(51) Int. Cl. H01L 25/16; H01L 23/00; H01L 23/31; H01L 23/495; H02M 3/07

(52) U.S. Cl. CPC H01L 25/16; H01L 23/49575; H01L 24/37; H01L 24/40; H02M 3/07; H01L 23/3121; H01L 24/32; H01L 24/73; H01L 2224/32245; H01L 2224/37124; H01L 2224/37147; H01L 2224/40245; H01L 2224/40265; H01L 2224/73263; H01L 2924/19041; H01L 2924/19042

(57) ABSTRACT

Integrated circuit (IC) packages for facilitating power converter systems and methods are provided. In one example, an IC package includes a leadframe. The IC package further includes an IC die coupled to the leadframe. The IC die includes a plurality of switches and a control circuit configured to control a state of at least a subset of the plurality of switches. The IC package further includes a plurality of metal clips. The IC package further includes a plurality of multi-layer ceramic capacitors coupled to the IC die via the plurality of metal clips. Each multi-layer ceramic capacitor is coupled to a subset of the plurality of switches via a subset of the plurality of metal clips. The IC package further includes a mold compound to encapsulate the leadframe, the IC die, the metal clips, and the multi-layer ceramic capacitors. Related systems and methods are also provided.

### TECHNICAL FIELD

The present disclosure relates generally to power converters, and more particularly for example, to integrated circuit packages for facilitating power converter systems and methods.

### BACKGROUND

Modern electronic devices may incorporate electronic components designed to operate within certain parameters, including parameters that relate to supply voltages. Power converters may be implemented within and/or coupled to electronic devices to provide appropriate power to various components of the electronic devices based on voltages supplied to the power converters.

### SUMMARY

In one or more embodiments, an integrated circuit package includes a leadframe. The package further includes an integrated circuit die coupled to the leadframe. The die includes a plurality of switches. The die further includes a control circuit configured to control a state of at least a subset of the plurality of switches. The package further includes a plurality of metal clips. The package further includes a plurality of multi-layer ceramic capacitors coupled to the die via the plurality of metal clips. Each of the plurality of multi-layer ceramic capacitors is coupled to a subset of the plurality of switches via a subset of the plurality of metal clips. The package further includes a mold compound to encapsulate the leadframe, the die, the plurality of metal clips, and the plurality of multi-layer ceramic capacitors.

In one or more embodiments, a method of assembling an integrated circuit package includes providing a leadframe. The method further includes attaching an integrated circuit die to the leadframe. The die includes a plurality of switches. The die further includes a control circuit configured to control a state of at least a subset of the plurality of switches. The method further includes attaching a plurality of metal clips to the die. The method further includes attaching a plurality of multi-layer ceramic capacitors to the plurality of metal clips such that each of the plurality of multi-layer ceramic capacitors is coupled to a subset of the plurality of switches via a subset of the plurality of metal clips. The method further includes encapsulating the leadframe, the die, the plurality of metal clips, and the plurality of multi-layer ceramic capacitors with a mold compound.

The scope of the disclosure is defined by the claims, which are incorporated into this section by reference. A more complete understanding of embodiments of the present disclosure will be afforded to those skilled in the art, as well as a realization of additional advantages thereof, by a consideration of the following detailed description of one or more embodiments. Reference will be made to the appended sheets of drawings that will first be described briefly.

### BRIEF DESCRIPTION OF THE DRAWINGS

FIG. 1 illustrates an example device in which an integrated circuit package for facilitating power conversion may be implemented in accordance with one or more embodiments of the present disclosure.

FIG. 2 illustrates a block diagram of a power converter in accordance with one or more embodiments of the present disclosure.

FIG. 3A illustrates a block diagram of an example switched-capacitor circuit implemented in a single package in accordance with one or more embodiments of the present disclosure.

FIG. 3B illustrates a block diagram of another example switched-capacitor circuit implemented in a single package in accordance with one or more embodiments of the present disclosure.

FIG. 4 illustrates a circuit diagram of an example power converter in accordance with one or more embodiments of the present disclosure.

FIG. 5A illustrates a side view of an example package for implementing a power converter (or portion thereof) in accordance with one or more embodiments of the present disclosure.

FIG. 5B illustrates a top view of an example layout of the package of FIG. 5A in accordance with one or more embodiments of the present disclosure.

FIG. 6A illustrates a side view of another example package for implementing a power converter (or portion thereof) in accordance with one or more embodiments of the present disclosure.

FIG. 6B illustrates a top view of an example layout of the package of FIG. 6A in accordance with one or more embodiments of the present disclosure.

FIG. 7 illustrates a circuit diagram of an example power converter in accordance with one or more embodiments of the present disclosure.

FIGS. 8 and 9 each illustrate a top view of an example layout of a package for implementing a power converter (or portion thereof) in accordance with one or more embodiments of the present disclosure.

FIGS. 10, 11, and 12 each illustrate a side view of an example package for implementing a power converter (or portion thereof) in accordance with one or more embodiments of the present disclosure.

FIG. 13 illustrates a flow diagram of an example process of assembling a package for facilitating power conversion in accordance with one or more embodiments of the present disclosure.

Embodiments of the present disclosure and their advantages are best understood by referring to the detailed description that follows. It is noted that sizes of various components and distances between these components are not drawn to scale in the figures. It should be appreciated that like reference numerals are used to identify like elements illustrated in one or more of the figures.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced using one or more embodiments. In one or more instances, structures and components are shown in block diagram form in order to avoid obscuring the concepts of the subject technology. One or more embodiments of the subject disclosure are illustrated by and/or described in connection with one or more figures and are set forth in the claims.

In one or more embodiments, integrated circuit (IC) packages (e.g., also referred to simply as packages) for facilitating power converter systems and methods are provided. In one embodiment, an IC package includes a leadframe, one or more IC die (e.g., also referred to simply as die), one or more capacitors, and a mold compound for encapsulating components of the IC package. The IC package may be a quad flat no-leads package (QFN package) in some embodiments, although other package types may be used in other embodiments. The leadframe may provide an interface for propagation of signals between the IC package and one or more components external to the IC package as well as provide mechanical support for each IC die and/or other components of the IC package. In some aspects, to provide thermal relief, one or more openings (e.g., also referred to as a cavity) may be formed in the IC package. For example, each opening may be formed by removing a portion of the mold compound to expose at least a portion of a top surface of a capacitor of the IC package. In some cases, a heat sink may be coupled to one or more of the opening(s) to further facilitate thermal relief.

The IC package may include metal clips to couple (e.g., electrically connect) each capacitor to an IC die. Each metal clip may include, by way of non-limiting examples, copper, aluminum, and/or other appropriate metal or metallic material (e.g., having very low resistance) to electrically connect components. The components of the IC package may be attached to each other using attachment elements. An attachment element may include, by way of non-limiting examples, solder, adhesive (e.g., conductive adhesive), or generally any element appropriate to attach (e.g., fixedly secure) one component to another component. In some cases, the attachment element may be conductive to facilitate propagation of electrical signals between components attached using the attachment element. As one example, to provide an electrical path between a capacitor and a die, a metal clip may be attached to the die via an attachment element and attached to the capacitor via another attachment element.

An IC die of the package may include switches and one or more control circuits (e.g., also referred to as controllers, controller circuits, control units, or variation thereof). In some aspects, the switches are lateral switches. In other aspects, the switches may include vertical switches or a combination of vertical and lateral switches. In some aspects, the switches may include transistors (e.g., field effect transistors (FETs)). As one example, the switches may be laterally-diffused metal-oxide semiconductor (LDMOS) FETs. In some cases, one or more of the switches may be a power switch (e.g., power FET). A power switch may be formed of numerous smaller switches (e.g., FETs) connected in parallel (e.g., with a metal). In some cases, power switches may facilitate/accommodate applications involving a large amount of current while avoiding overheating.

A state of each switch may be controlled by a control circuit. Each switch may be closed (e.g., on/closed state) or open (e.g., off/open state). A control circuit may include drivers (e.g., gate drivers for switches implemented using transistors), level shifters, and logic for controlling the drivers and the level shifters. For a given driver (e.g., gate driver), the driver is generally disposed in proximity to the switch whose state is controlled by the driver.

Each capacitor of the power converter is coupled to a subset of the switches of the IC die. In some cases, each capacitor is arranged directly above the switches to which the capacitor is electrically connected. For a given capacitor, properly orienting the capacitor relative to its respective switches to allow placement/coupling of the capacitor directly above the switches reduces a routing resistance (e.g., by shortening a distance currents need to flow) between the capacitor and the die relative to a case in which the capacitor is not directly above its respective switches and a routing circuit is used to appropriate route signals between the capacitor and its respective switches. In general, routing resistance may negatively impact efficiency performance of power converters. In some embodiments, the capacitors C₁ and C₂ are multi-layer ceramic capacitors (MLCCs). In some aspects, MLCCs may be used to provide greater capacitor density and/or voltage rating relative to other capacitor types, such as integrated capacitors (e.g., planar capacitors, trench capacitors).

In some embodiments, the switches of the IC die and the capacitor(s) coupled to the switches may form a switched-capacitor circuit. The switched-capacitor circuit may generate an output signal (e.g., output voltage) based on an input signal (e.g., input voltage) through turning on and off of its switches as a function of time. In this regard, the control circuit(s) of the IC die may control the state of each switch of the IC die as appropriate over time to cause generation of a desired output signal.

In some aspects, the package may include multiple IC die, with each die including one or more switches and one or more control circuits. Control circuitry may be split (e.g., distributed) across the multiple IC die. As provided above, for a given driver of the control circuitry, the driver is generally disposed in proximity to the switch whose state is controlled by the driver. In this regard, each switch on a die is generally controlled by a control circuit on the same die as the switches. In some aspects, the multiple IC die may be part of a reconstituted wafer. In some cases, the use of multiple IC die may be primarily to accommodate a size of the capacitor(s) on the switches of each IC die. In this regard, the use of multiple die may allow for chip real estate savings and associated cost savings relative to a case in which a single, large IC die is used. For example, rather than use a single, large die (e.g., requiring more die material such as silicon and thus higher material cost) to accommodate a size of the capacitor(s) to be coupled to the switches of the single die, the multiple die (with each die including its respective switches) may be disposed at positions (e.g., within a reconstituted wafer in some cases) as appropriate to accommodate/fit the size of the capacitor(s).

Electronic devices may include and/or otherwise operate with electronic components designed to operate within certain parameters, including those related to supply voltages for example. Using various embodiments, power converters formed at least in part with an IC package described herein may be included in such electronic devices to provide appropriate power to various components. In some embodiments, the IC package may be used to implement power converters (or portion thereof) such as, by way of non-limiting examples, multi-level power converters and charge pumps. For example, higher performance microprocessors may include billions of transistors, may switch at several gigahertz, and/or may consume hundreds of amperes of current at relatively lower voltages (e.g., less than 1.0 V in some cases). Use of one or more IC packages for facilitating power conversion in accordance with one or more embodiments may allow for power conversion capabilities that may be readily scaled in size and/or capabilities for a variety of applications having different voltage and/or current needs.

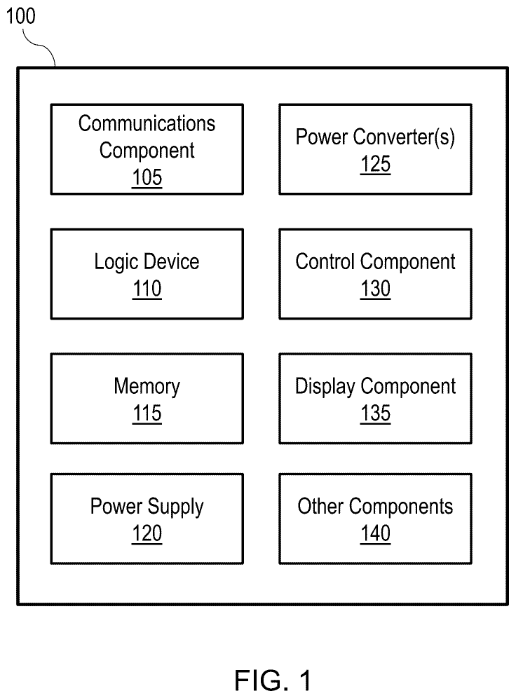

FIG. 1 illustrates an example device 100 in which an IC package for facilitating power conversion may be implemented in accordance with one or more embodiments of the present disclosure. Not all of the depicted components may be required, however, and one or more embodiments may include additional components not shown in the figure. Variations in the arrangement and type of the components may be made without departing from the spirit or scope of the claims as set forth herein. Additional, fewer, and/or different components may be provided.

The device 100 may be, may include, or may be a part of, a mobile phone, a computer, a tablet device, a game console, a personal digital assistant, a wearable device, a video player and/or recorder, an audio player and/or recorder, and/or generally any device that may be operable to facilitate power conversion. The device 100 includes a communications component 105, a logic device, a memory 115, a power supply 120, a power converter(s) 125, a control component 130, a display component 135, and other components 140. The communications component 105 may facilitate wireless and/or wired communication between components within the device 100 and/or between the device 100 and one or more other devices. In this regard, the communications component 105 may facilitate communication by the device 100 using one or more wireless communication technologies, such as Wi-Fi (IEEE 802.11ac, 802.11ad, etc.), cellular (3G, 4G, 5G, etc.), Bluetooth™, etc., and/or one or more wired communication technologies. In some cases, various components of the device 100, such as the logic device 110 and the memory 115, may be implemented using a single chip or multiple chips. The communications component 105 may facilitate wired and/or wireless inter-chip and/or intra-chip connections between these components.

The logic device 110 may be implemented as one or more of a general-purpose processor, a digital signal processor (DSP), an application-specific integrated circuit (ASIC), a microcontroller, a programmable logic device (PLD) (e.g., a field-programmable gate array (FPGA)), or other logic device. The logic device 110 may be configured through hardwiring, software execution, or a combination of both to facilitate operation of the device 100. In this regard, the logic device 110 may be configured to interface and communicate with the various other components (e.g., 105, 115, 120, 125, 130, 135, and/or 140) of the device 100 to perform such operation. For example, in some embodiments, the logic device 110 may communicate with the power converter(s) 125 to facilitate generation of a desired output signal (e.g., desired output voltage) by the power converter(s) 125.

The memory 115 may include one or more memory devices designed to retain data, such as software instructions for execution by the logic device 110. The memory 115 may include volatile memories and/or non-volatile memories, such as random-access memory (RAM), dynamic RAM (DRAM), static RAM (SRAM), non-volatile random-access memory (NVRAM), read-only memory (ROM), programmable read-only memory (PROM), erasable programmable read-only memory (EPROM), electrically-erasable programmable read-only memory (EEPROM), flash memory, hard disk drives, and/or other memory types. As discussed above, the logic device 110 may be configured to execute software instructions stored in the memory 115 so as to perform method and process steps and/or operations.

The power supply 120 may supply power to operate the device 100, such as by supplying power to the various components of the device 100. The power supply 120 may be, or may include, one or more batteries (e.g., rechargeable batteries, non-rechargeable batteries). The batteries may be a lithium ion battery, lithium polymer battery, nickel cadmium battery, nickel metal hydride battery, or any other battery suitable to supply power to operate the device 100. Alternatively or in addition, the power supply 120 may be, or may include, one or more solar cells. The solar cells may be utilized to supply power to operate the device 100 and/or to charge one or more rechargeable batteries.

The power converter(s) 125 may receive power from the power supply 120 and generate appropriate power to various components of the device 100 (e.g., based on the power received from the power supply 120). At least one of the power converter(s) 125 may include an IC package in accordance with one or more embodiments, as further described herein. By way of non-limiting examples, the power converter(s) 125 may include multi-level power converters (e.g., multi-level buck converters, multi-level boost converters), charge pumps, and/or power converters associated with other architectures.

The control component 130 may include a user input and/or an interface device, such as a rotatable knob, push buttons, keyboard, and/or other devices, that is adapted to generate a user input control signal. The logic device 110 may be configured to receive control input signals from a user via the control component 130 and respond to any received control input signals. As one example, the user input may indicate a desired output voltage to be generated by one or more of the power converter(s) 125.

The display component 135 may include an image display device (e.g., a liquid crystal display (LCD)) or various other types of generally known video displays or monitors. The logic device 110 may be configured to display data on the display component 135. In some aspects, the control component 130 may be implemented as part of the display component 135. For example, a touchscreen of the device 100 may provide both the control component 130 (e.g., for receiving user input via gestures) and the display component 135.

The other components 140 may be used to implement any features of the device 100 as may be desired for various applications. In some aspects, the other components 140 may include, by way of non-limiting examples, clock generators, counters, timers, and sensors. A sensor may respond to a stimulus (e.g., heat, light, sound pressure, etc.), such as generating a signal(s) in response to the stimulus. Non-limiting examples of a sensor may include an accelerometer, a gyroscope, a thermometer, a light sensor, a barometer, a proximity sensor, a camera, a microphone, and/or any combination thereof.

In some embodiments, various components of the device 100 may be combined and/or implemented or not depending on application. In one example, the logic device 110 may be combined with the memory 115, the power supply 120, the power converter(s) 125, the display component 135, and/or a sensor(s) of the other components 140. In another example, the logic device 110 may be combined with the power converter(s) 125, such that certain functions of the logic device 110 are performed by circuitry (e.g., a processor, a microprocessor, a logic device, a microcontroller, etc.) within the power converter(s) 125. In yet another example, the device 100 does not include the control component 130 and/or the display component 135.

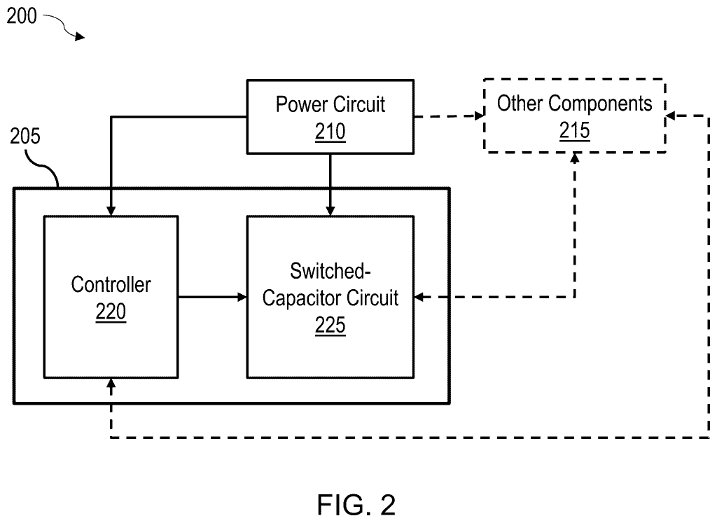

FIG. 2 illustrates a block diagram of a power converter 200 in accordance with one or more embodiments of the present disclosure. Not all of the depicted components may be required, however, and one or more embodiments may include additional components not shown in the figure. Variations in the arrangement and type of the components may be made without departing from the spirit or scope of the claims as set forth herein. Additional, fewer, and/or different components may be provided. In some embodiments, by way of non-limiting examples, the power converter 200 may include a multi-level power converter (e.g., multi-level buck converter, multi-level boost converter), a charge pump, and/or a power converter associated with other architectures.

The power converter 200 includes a package 205, a power circuit 210, and other components 215. In some cases, the other components 215 are optional. In this regard, dashed arrows in FIG. 2 represent connections that may be optional in some embodiments and a dashed block (e.g., the other components 215) represents a component that may be optional in some embodiments.

The package 205 includes a controller 220 and a switched-capacitor circuit 225. In an embodiment, the package 205 may be a QFN package. The switched-capacitor circuit 225 includes switches (e.g., FETs such as LDMOS FETs) and one or more capacitors coupled to the switches. In some cases, each capacitor is arranged directly above the switches to which the capacitor is electrically connected. The controller 220 may control a state (e.g., on state, off state) of each switch of the switched-capacitor circuit 225. The switched-capacitor circuit 225 may generate an output signal (e.g., output voltage) based on an input signal (e.g., input voltage) from the power circuit 210 through changing the state of its switches as a function of time. In this regard, the controller 220 may control the state of each switch of the switched-capacitor circuit 225 over time as appropriate to cause generation of a desired output signal. In an aspect, at a given point in time, the state of all the switches may collectively be referred to as a combination of states of the switches. As such, the controller 220 may effectuate control of the switches to alter between different combinations of states over time to provide the desired output signal. In some embodiments, the controller 220 and the switches of the switched-capacitor circuit 225 may be implemented on one or more die, as further described herein.

The power circuit 210 may provide power to operate the power converter 200, such as by providing power to the package 205 (e.g., the controller 220 and the switched-capacitor circuit 225) and, in some cases, the other components 215. In an embodiment, the power circuit 210 may be, or may be coupled to, a power supply, such as the power supply 120 of FIG. 1. In some cases, the power circuit 210 may include circuitry, such as switching circuitry, that selectively couples the power supply to the package 205 and/or the other components 215. For example, when the package 205 is not being used, the power circuit 210 may disconnect the package 205 from the power supply to deactivate the package 205 (e.g., to allow power savings).

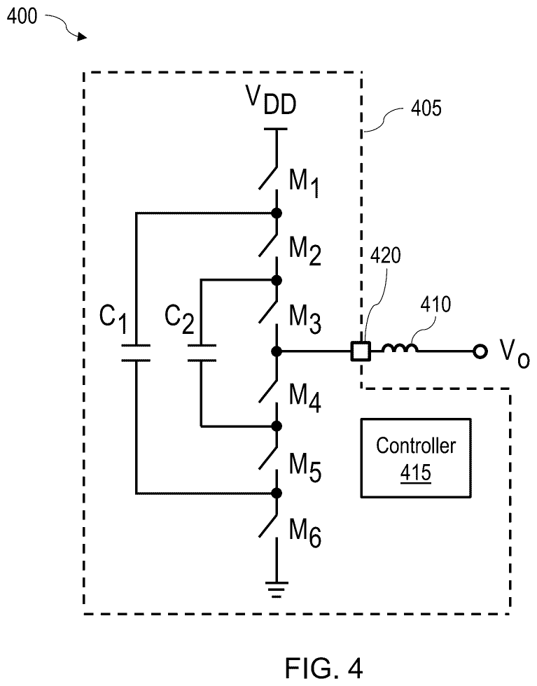

The other components 215 may include one or more energy storage elements, one or more additional packages, and/or generally any other component(s) that may be included as part of the power converter 200. The other components 215 may, but need not, be coupled to the power circuit 210, the controller 220, or the switched-capacitor circuit 225. In some cases, the power circuit 210 may provide signals (e.g., voltage, current) to the other components 215. An energy storage element may include a capacitor (e.g., for storing energy in an electric field) or an inductor (e.g., for storing energy in a magnetic field). In this regard, in some cases, the other components 215 may include one or more capacitors and/or one or more inductors external to and coupled to the package 205. As one example, as described with respect to FIG. 4, the switched-capacitor circuit 225 may be coupled to an inductor (e.g., a component among the other components 215) to form a multi-level power converter. In some cases, one or more inductors may be part of the package 205. As another example, the other components 215 may include one or more capacitors external to the package 205. The external capacitor(s) may counteract a parasitic loop inductance associated with the package 205. The parasitic loop inductance may store energy associated with operation of the switched-capacitor circuit 225 and lose the stored energy in response to changes in the states of the switches of the switched-capacitor circuit 225. As such, the parasitic loop inductance is a source of energy loss. In some aspects, the other components 215 may include another package and/or may include a switched-capacitor circuit and associated logic (e.g., controller to control switches), in which case the other components 215 may be controlled exclusively by logic included as part of the other components 215 or such logic in conjunction with logic from the controller 220.

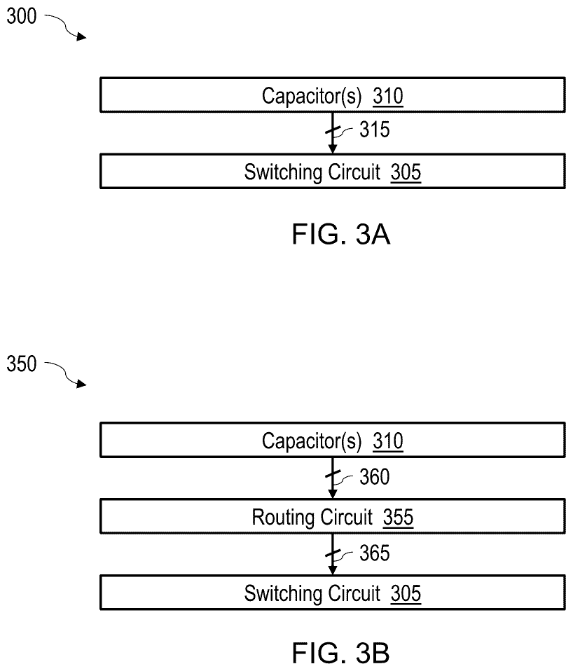

FIG. 3A illustrates a block diagram of an example switched-capacitor circuit 300 implemented in a single package in accordance with one or more embodiments of the present disclosure. In an embodiment, the switched-capacitor circuit 300 may be, may include, or may be a part of, the switched-capacitor circuit 225 of FIG. 2.

The switching circuit 305 includes switches (e.g., FETs). In some aspects, the switches are lateral switches. In other aspects, the switches may include vertical switches or a combination of vertical switches and lateral switches. Each of the capacitor(s) 310 (e.g., MLCC) is arranged directly above the switches to which the capacitor is electrically connected. In one case, each capacitor may be coupled to the respective switches of the switching circuit 305 using one or more of the connections 315. As an example, one end of a capacitor may be coupled to a first set of switches via one of the connections 315 (e.g., a first metal clip and solder for attaching the first metal clip to the capacitor and the first set of switches) and another end of the capacitor may be coupled to a second set of switches via another of the connections 315 (e.g., a second metal clip and solder for attaching the second metal clip to the capacitor and the second set of switches). Placement of the capacitor(s) 310 directly above the respective switches of each capacitor may allow for lower routing resistance relative to cases in which the capacitor(s) 310 are farther from the switches, such as when a routing circuit is used to connect the capacitor(s) 310 and the switching circuit 305.

FIG. 3B illustrates a block diagram of an example switched-capacitor circuit 350 implemented in a single package in accordance with one or more embodiments of the present disclosure. In an embodiment, the switched-capacitor circuit 350 may be, may include, or may be a part of, the switched-capacitor circuit 225 of FIG. 2. The description of FIG. 3A generally applies to FIG. 3B, with differences between FIGS. 3A and 3B and other description provided herein.

The switched-capacitor circuit 350 includes the switching circuit 305 and the capacitor(s) 310. The switched-capacitor circuit 350 also includes a routing circuit 355, connections 360 between the routing circuit 355 and the capacitor(s) 310, and connections 365 between the routing circuit 355 and the switching circuit 305. Compared to the switched-capacitor circuit 300 in which the capacitor(s) 310 are disposed directly above the switches of the switching circuit 305 to which the capacitor(s) 310 electrically connects, the routing circuit 355 provides appropriate connections/routing between the capacitor(s) 310 and the switches of the switching circuit 305. The routing circuit 355 may provide flexibility in positioning of the capacitor(s) 310 and/or the switches of the switching circuit 305 while being associated with higher routing resistance relative to when the capacitor(s) 310 are disposed directly above the switches.

FIG. 4 illustrates a circuit diagram of an example power converter 400 in accordance with one or more embodiments of the present disclosure. Not all of the depicted components may be required, however, and one or more embodiments may include additional components not shown in the figure. Variations in the arrangement and type of the components may be made without departing from the spirit or scope of the claims as set forth herein. Additional, fewer, and/or different components may be provided.

The power converter 400 includes a package 405 (e.g., QFN package) and an inductor 410 coupled to the package 405. The package 405 includes switches M₁ through M₆, capacitors C₁ and C₂, and a controller 415. In some embodiments, the switches M₁ through M₆ and the controller 415 may be integrated in one or more die (e.g., silicon die) and the capacitors C₁ and C₂ may each be coupled to a respective set of switches on the die, as further described herein. In some embodiments, the power converter 400 may be, may include, or may be a part of the power converter 200 of FIG. 2, in which the switches M₁ through M₆ and the capacitors C₁ and C₂ may collectively implement the switched-capacitor circuit 225, the controller 415 may implement the controller 220, and the inductor 410 may be included as part of the other components 215.

The switch M₁ is coupled to the switch M₂ and the capacitor C₁. The switch M₂ is coupled to the switches M₁ and M₃ and the capacitors C₁ and C₂. The switch M₃ is coupled to the switches M₂ and M₄ and the capacitor C₂. The switch M₄ is coupled to the switches M₃ and M₅ and the capacitor C₂. The switch M₅ is coupled to the switches M₄ and M₆ and the capacitors C₁ and C₂. The switch M₆ is coupled to the switch M₅, the capacitor C₁, and ground. In some aspects, the switches M₁ through M₆ are lateral switches. In other aspects, the switches M₁ through M₆ may include vertical switches or a combination of vertical and lateral switches. In some aspects, the switches M₁ through M₆ are transistors (e.g., FETs). As one example, the switches M₁ through M₆ may be LDMOS FETs. In some cases, one or more of the switches M₁ through M₆ may be a power switch (e.g., power FET). A power switch may be formed of numerous smaller switches connected in parallel. In some cases, power switches may facilitate/accommodate applications involving a large amount of current while avoiding overheating.

The capacitor C₁ is coupled to a node between the switches M₁ and M₂ and a node between the switches M₅ and M₆. The capacitor C₂ is coupled to a node between the switches M₂ and M₃ and a node between the switches M₄ and M₅. The inductor 410 is coupled to a node 420 between the switches M₃ and M₄. In some embodiments, the capacitors C₁ and C₂ may be MLCCs. In some aspects, MLCCs may be used to provide higher capacitor density and/or voltage rating relative to other capacitor types, such as integrated capacitors (e.g., planar capacitors, trench capacitors). In some cases, the capacitors C₁ and C₂ may be referred to as fly capacitors or flying capacitors.

The controller 415 controls a state (e.g., on state, off state) of each of the switches M₁ through M₆. In this regard, the controller 415 may include drivers (e.g., gate drivers for switches implemented using transistors), level shifters, and logic for controlling the drivers and the level shifters. For example, the controller 415 may include a first gate driver that applies a voltage at an appropriate level to the switch M₁ to close (e.g., set M₁ to on state) or open (e.g., set M₁ to off state) the switch M₁, a second gate driver that applies a voltage at an appropriate level to the switch M₂ to close or open the switch M₂, and so forth for the remaining switches M₃ through M₆. Although the controller 415 is shown as a single block within the package 405, the controller 415 may include/represent components distributed throughout the package 405 (e.g., throughout one or more die in the package 405), including those components for controlling the state of the switches M₁ through M₆. In this regard, for a given driver (e.g., gate driver), the driver is generally disposed in proximity to the switch whose state is controlled by the driver.

Through control of the state of each switch M₁ through M₆ as a function of time by the controller 415, the package 405 may generate a signal (e.g., voltage, current) at the node 420. The node 420 may be considered an output node or simply an output of the package 405. The node 420 may be considered an interface or a connection between the package 405 and the inductor 410 external to the package 405. In some cases, the node 420 may be, or may be coupled to, a leadframe of the package 405. The inductor 410 may be coupled to a load (not shown). An LC filter formed by the inductor 410 and a load capacitance (not shown) may filter the signal provided at the node 420 by the package 405 to provide an output voltage Vₒ of the power converter 400.

In accordance with one or more embodiments, the power converter 400 may implement a four-level buck converter. An input voltage V_{DD} is provided to the package 405 (e.g., V_{DD} is coupled to the switch M₁) and divided (e.g., chopped) by the switches M₁ and M₆ and the capacitors C₁ and C₂. The input voltage V_{DD} may be provided by a power supply external to the package 405, such as the power supply 120 of FIG. 1. The controller 415 may set a state of each of the switches M₁ through M₆ as a function of time based on a desired output voltage Vₒ. The desired output voltage Vₒ may be one of four predetermined direct current (DC) voltage levels that may be generated by the power converter 400 based on the input voltage V_{DD}. In this regard, the package 405 may generate, at the node 420, a pulsating voltage associated with the desired output voltage Vₒ through appropriate control of the state of each of the switches M₁ through M₆ as a function of time. An LC filter formed of the inductor 410 and a load capacitance (not shown) may filter this pulsating voltage provided at the node 420 to arrive at the desired output voltage Vₒ. To arrive at a different desired output voltage, the controller 415 may use different combinations of states of the switches M₁ through M₆ as a function of time to cause generation of a pulsating voltage that, in turn, gets filtered to arrive at this different output voltage.

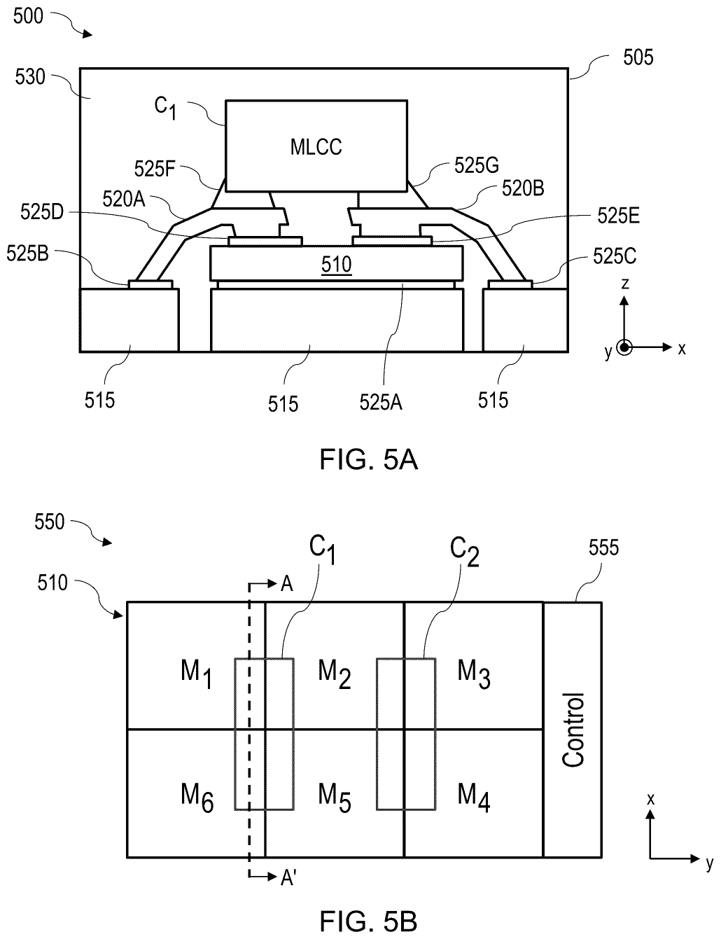

FIG. 5A illustrates a side view 500 of an example package 505 for implementing a power converter (or portion thereof) in accordance with one or more embodiments of the present disclosure. FIG. 5B illustrates a top view 550 of an example layout of the package 505 in accordance with one or more embodiments of the present disclosure. For explanatory purposes, the side view 500 of FIG. 5A corresponds to a side view along a line A-A′ indicated in the top view 550. Not all of the depicted components may be required, however, and one or more embodiments may include additional components not shown in the figures. Variations in the arrangement and type of the components may be made without departing from the spirit or scope of the claims as set forth herein. Additional, fewer, and/or different components may be provided. In this regard, example variations may be described with respect to other figures. In some embodiments, the package 505 may implement a portion of the power converter 400 of FIG. 4, in which the package 505 may implement the package 405. To provide a frame of reference, x-, y-, and z-axes are shown in FIG. 5A and x- and y-axes are shown in FIG. 5B.

The package 505 includes an IC die 510, a leadframe 515, metal clips 520A and 520B, attachment elements 525A-G, capacitors C₁ and C₂, and a mold compound 530. In some embodiments, the package 505 may be a QFN package. The die 510 is attached to the leadframe 515 via the attachment element 525A. In general, two attached components may be considered to be and referred to as being fixedly secured, fixedly connected, or fixedly coupled to each other. The metal clip 520A is attached to the leadframe 515 via the attachment element 525B and attached to the die 510 via the attachment element 525D. The metal clip 520B is attached to the leadframe 515 via the attachment element 525C and attached to the die 510 via the attachment element 525E. The capacitor C₁ is attached to the metal clip 520A via the attachment element 525F and attached to the metal clip 520B via the attachment element 525G. Similarly, the capacitor C₂ may be attached to corresponding metal clips (not shown) via corresponding attachment elements (not shown).

The leadframe 515 provides an interface for propagation of signals between the package 505 and one or more components external to the package 505 as well as provide mechanical support for the die 510 and other components of the package 505. In an embodiment, for example, with reference to the multi-level power converter 400, the leadframe 515 may provide signals (e.g., voltages, currents) to the node 420 of the package 405 or otherwise represent/implement the node 420. For example, a voltage at the node 420 may be provided external to the package 405 and to the inductor 410, thus allowing the package 405 and the inductor 410 to collectively implement the multi-level power converter 400.

The metal clips 520A and 520B connect (e.g., electrically connect) the capacitor C₁ to the die 510 and, similarly, metal clips (not shown) connect the capacitor C₂ to the die 510. In this regard, the attachment element 525D, the metal clip 520A, and the attachment element 525F form one electrical path between the capacitor C₁ and the die 510, and the attachment element 525E, the metal clip 520B, and the attachment element 525G form another electrical path between the capacitor C₁ and the die 510. Similar electrical paths may be formed between the capacitor C₂ and the die 510 via attachment elements and metal clips. The metal clips 520A and 520B may include, by way of non-limiting examples, copper, aluminum, and/or other appropriate metal or metallic material to electrically connect components. In some cases, attachment of the metal clips 520A and 520B to the leadframe 515 may be optional, such as when the metal clips 520A and 520B are used only to connect the capacitor C₁ to the die 510 (and not to components external to the package 505) as described with respect to, for example, FIG. 10.

Each of the attachment elements 525A-G for attaching components of the package 505 may be solder, conductive adhesive, or generally any element appropriate to attach (e.g., fixedly secure) one component to another component while facilitating propagation of electrical signals between these attached components. In one example case, the attachment elements 525A-G may each include solder. In such a case, the die 510 may be soldered to the leadframe 515 as shown by the attachment element 525A; the metal clip 520A may be soldered to the leadframe 515 and the die 510 as shown by the attachment elements 525B and 525D, respectively; the metal clip 520B may be soldered to the leadframe 515 and the die 510 as shown by the attachment elements 525C and 525E, respectively; and the capacitor C₁ may be soldered to the metal clips 520A and 520B as shown by the attachment elements 525F and 525G, respectively.

It is noted that the package 505 shows one example arrangement with metal clips and attachment elements for coupling capacitors, die, and a leadframe. However, other techniques such as flip-chip bonding and and/or wire bonding may be used alternatively or in addition to those shown in the package 505. For example, one or more wire bonds may be used to connect the die 510 to the leadframe 515.

The mold compound 530 encapsulates the die 510, the leadframe 515, the metal clips 520A and 520B, the attachment elements 525A-G, and any additional component (if any) of the package 505 not explicitly shown in FIGS. 5A and 5B. In this regard, the mold compound 530 surrounds the various components of the package 505 (e.g., to provide support and protection). The mold compound 530 may be formed (e.g., using appropriate material(s)) to have appropriate mechanical properties (e.g., tensile strength, adhesive bond strength), electrical properties (e.g., electrical resistivity), and thermal properties (e.g., thermal conductivity, coefficient of thermal expansion) dependent on application (e.g., desired power converter characteristics, cost considerations, etc.) associated with the package 505. In some cases, the molding compound may include composite materials formed of epoxy resins, phenolic resins, silicas, and/or other materials.

With particular reference to FIG. 5B, the die 510 includes switches M₁ through M₆ and a control circuit 555. In some aspects, the switches M₁ through M₆ are lateral switches. In other aspects, the switches M₁ through M₆ may include vertical switches or a combination of vertical and lateral switches. In some aspects, the switches M₁ through M₆ are transistors (e.g., FETs such as LDMOS FETs). In some cases, one or more of the switches M₁ through M₆ may be a power switch (e.g., power FET). A power switch may be formed of numerous smaller switches connected in parallel. In some cases, power switches may facilitate/accommodate applications involving a large amount of current while avoiding overheating.

The capacitors C₁ and C₂ are each coupled to a respective subset of the switches implemented on the die 510. As shown in FIGS. 4 and 5B, a first end of the capacitor C₁ is coupled to the switches M₁ and M₂ and a second end of the capacitor C₁ is coupled to the switches M₅ and M₆. A first end of the capacitor C₂ is coupled to the switches M₂ and M₃ and a second end of the capacitor C₂ is coupled to the switches M₄ and M₅. For example, in FIG. 5A, the capacitor C₁ is coupled to its respective subset of the switches via the metal clips 520A and 520B.

In FIG. 5B, the capacitors C₁ and C₂ are each arranged such that they are directly above the switches to which they are electrically connected. In this regard, the capacitor C₁ is directly above M₁, M₂, M₆, and M₅. The capacitor C₂ is directly above M₂, M₃, M₄, and M₅. Placement/coupling of the capacitors C and C₂ directly above the switches reduces a routing resistance (e.g., by shortening the distance currents need to flow) between the capacitors C₁ and C₂ and the die 510 relative to a case the capacitors C₁ and C₂ are not directly above their respective switches and a routing circuit is used to appropriate route signals between the capacitors C₁ and C₂ and their respective switches. In some embodiments, the capacitors C₁ and C₂ are MLCCs. In some aspects, MLCCs may be used to provide higher capacitor density and/or voltage rating relative to other capacitor types, such as integrated capacitors (e.g., planar capacitors, trench capacitors). In some cases, the capacitors C₁ and C₂ may be referred to as fly capacitors or flying capacitors.

The control circuit 555 controls a state of each of the switches M₁ through M₆. In this regard, the control circuit 555 may include drivers (e.g., gate drivers), level shifters, and logic for controlling the drivers and the level shifters. For example, the control circuit 555 may include a first gate driver that applies a voltage at an appropriate level to the switch M₁ to close (e.g., set M₁ to on state) or open (e.g., set M₁ to off state) the switch M₁, a second gate driver that applies a voltage at an appropriate level to the switch M₂ to close or open the switch M₂, and so forth for the remaining switches M₃ through M₆. Although the control circuit 555 is shown as a single block/component on the die 510, the control circuit 555 may include/represent components distributed throughout the die 510, including those components for controlling the state of the switches M₁ through M₆. In this regard, for a given driver (e.g., gate driver), the driver is generally disposed in proximity to the switch whose state is controlled by the driver.

It is noted that the leadframe 515, the metal clips 520A and 520B, the attachment elements 525A-G, and the mold compound 530 are not shown in the top view 550 of the layout. It is further noted that, while the side view 500 and the top view 550 are described as being different views of the same power converter, the side view 500 may be associated with a power converter that has a different layout from that shown by the top view 550, such as a layout of a power converter that has more or fewer than six switches, and, similarly, the top view 550 may be associated with a power converter that has a different side view from the side view 500.

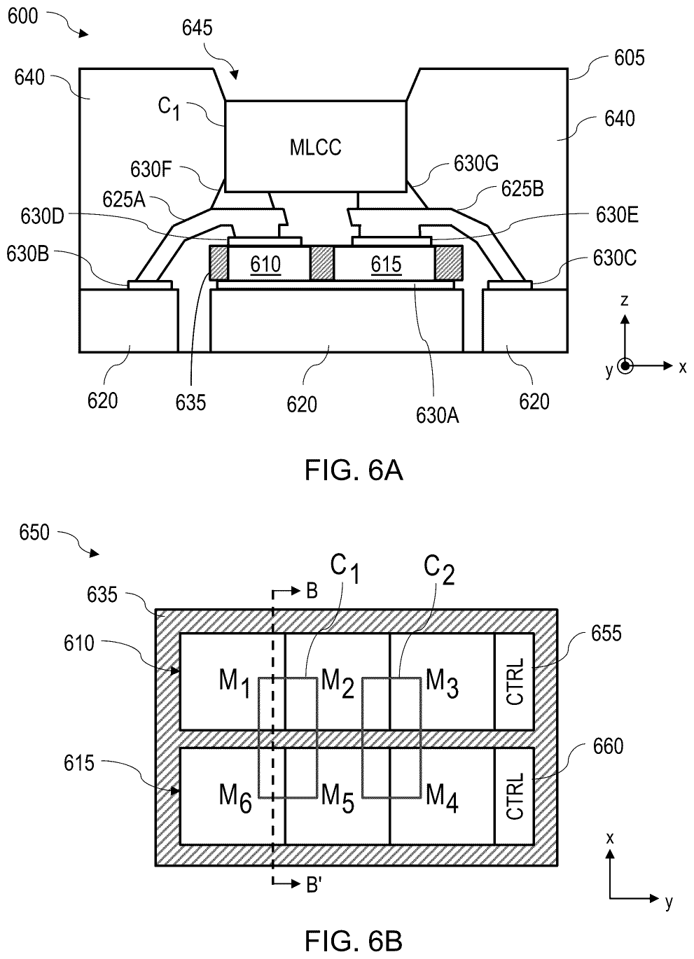

FIG. 6A illustrates a side view 600 of an example package 605 for implementing a power converter (or portion thereof) in accordance with one or more embodiments of the present disclosure. FIG. 6B illustrates a top view 650 of an example layout of the package 605 in accordance with one or more embodiments of the present disclosure. For explanatory purposes, the side view 600 of FIG. 6A corresponds to a side view along a line B-B′ indicated in the top view 650. Not all of the depicted components may be required, however, and one or more embodiments may include additional components not shown in the figures. Variations in the arrangement and type of the components may be made without departing from the spirit or scope of the claims as set forth herein. Additional, fewer, and/or different components may be provided. In some embodiments, the package 605 may implement a portion of the multi-level power converter 400 of FIG. 4, in which the package 605 may implement the package 405. To provide a frame of reference, x-, y-, and z-axes are shown in FIG. 6A and x- and y-axes are shown in FIG. 6B.

The description of FIGS. 5A and 5B (e.g., description related to common features such as a leadframe, metal clips, and so forth) generally applies to FIGS. 6A and 6B, with examples of differences between FIGS. 5A-5B and FIGS. 6A-6B and other description provide herein. It is noted that, while the side view 600 and the top view 650 are described as being different views of the same power converter, the side view 600 may be associated with a power converter that has a different layout from that shown by the top view 650 and, similarly, the top view 650 may be associated with a power converter that has a different side view from the side view 600.

The package 605 (e.g., QFN package) includes IC die 610 and 615, a leadframe 620, metal clips 625A and 625B, attachment elements 630A-G, capacitors C₁ and C₂, and mold compounds 635 and 640. The die 610 and 615 are attached to the leadframe 620 via the attachment element 630A. The metal clip 625A is attached to the leadframe 620 via the attachment element 630B and attached to the die 610 via the attachment element 630D. The metal clip 625B is attached to the leadframe 620 via the attachment element 630C and attached to the die 615 via the attachment element 630E. The capacitor C₁ is attached to the metal clip 625A via the attachment element 630F and attached to the metal clip 625B via the attachment element 630G. Similarly, the capacitor C₂ may be attached to corresponding metal clips (not shown) via corresponding attachment elements (not shown).

The leadframe 620 provides an interface for propagation of signals between the package 605 and one or more components external to the package 605. In an embodiment, for example, with reference to the multi-level power converter 400, the leadframe 620 may provide signals (e.g., voltages, currents) to the node 420 of the package 405 or otherwise represent/implement the node 420. For example, a voltage at the node 420 may be provided external to the package 405 and to the inductor 410, thus allowing the package 405 and the inductor 410 to collectively implement the power converter 400.

The metal clip 625A connects (e.g., electrically connects) the capacitor C₁ to the die 610. The metal clip 625B connects (e.g., electrically connects) the capacitor C₁ to the die 615. Similarly, metal clips (not shown) connect the capacitor C₂ to the die 610 and 615. In this regard, the attachment element 630D, the metal clip 625A, and the attachment element 630F form an electrical path between the capacitor C₁ and the die 610, and the attachment element 630E, the metal clip 625B, and the attachment element 630G form an electrical path between the capacitor C₁ and the die 615. Similar electrical paths may be formed between the capacitor C₂ and the die 610 and 615 via attachment elements and metal clips.

The mold compound 635 is disposed between and around the die 610 and 615 while leaving a bottom surface (e.g., also referred to as a back surface) and a top surface (e.g., also referred to as a front surface) of the die 610 and 615 exposed. In some aspects, the die 610 and 615 may be reconstituted die, although other techniques may be used to form the die 610 and 615. In this regard, the die 610 and 615 may form two die of a reconstituted wafer. In some cases, usage of multiple die may allow for chip real estate savings and associated cost savings. For example, rather than use a single, large die (e.g., requiring more die material such as silicon and thus higher material cost) to accommodate a size of the capacitors C₁ and C₂, the die 610 and 615 may be disposed at positions within the reconstituted wafer as appropriate to accommodate the size of the capacitors C₁ and C₂. The mold compound 640 encapsulates the die 610 and 615, the leadframe 620, the metal clips 625A and 625B, the attachment elements 630A-G, the mold compound 635, and any additional component (if any) of the package 605 not explicitly shown in FIGS. 6A and 6B. The mold compound 635 and the mold compound 640 may be formed of the same or different material.

The package 605 has an opening 645 defined therein to expose a top surface of at least a portion of the capacitor C₁. The opening 645 may provide a thermal path for providing thermal relief for the package 605. In some cases, the package 605 may include one or more additional openings to provide one or more additional thermal paths. For example, the package 605 may have at least one additional opening defined therein to expose a top surface of at least a portion of the capacitor C₂. In some aspects, the opening 645 may be formed by removing a portion of the mold compound 640 to define the opening 645. For example, to form the opening 645, a portion of a top surface of the mold compound 640 may be grinded downwards close to a top surface of the capacitor C₁ and then an acid applied to the mold compound 640 to expose the top surface of the capacitor C₁. In some cases, a heat sink (not shown) may be coupled to the exposed top surface of the capacitor C₁ (e.g., to further facilitate thermal relief). One or more additional opening(s) may be formed similarly using a similar technique or using other techniques. A heat sink may be coupled to one or more of the additional opening(s).

With particular reference to FIG. 6B, the die 610 includes switches M₁, M₂, and M₃ and a control circuit 655, and the die 615 includes switches M₄, M₅, and M₆ and a control circuit 660. In some aspects, the switches M₁ through M₆ are lateral switches. In other aspects, the switches M₁ through M₆ may include vertical switches or a combination of vertical and lateral switches. In some aspects, the switches M₁ through M₆ are transistors, such as LDMOS transistors. In some cases, one or more of the switches M₁ through M₆ may be a power switch (e.g., power FET). In an aspect, the switches M₁, M₂, and M₃ may be referred to as high side switches and the switches M₄, M₅, and M₆ may be referred to as low side switches.

The capacitors C₁ and C₂ are each coupled to a respective subset of the switches implemented on the die 610 and 615. As shown in FIGS. 4 and 6B, a first end of the capacitor C₁ is coupled to the switches M₁ and M₂ of the die 610 and a second end of the capacitor C₁ is coupled to the switches M₅ and M₆ of the die 615. A first end of the capacitor C₂ is coupled to the switches M₂ and M₃ of the die 610 and a second end of the capacitor C₂ is coupled to the switches M₄ and M₅ of the die 615. For example, in FIG. 6A, the capacitor C₁ is coupled to its respective subset of the switches via the metal clips 625A and 625B. As shown in FIG. 6B, the capacitors C₁ and C₂ are each arranged such that they are directly above the switches to which they are electrically connected. In some embodiments, the capacitors C₁ and C₂ are MLCCs.

The control circuit 655 may control a state of each of the switches M₁, M₂, and M₃ of the die 610. The control circuit 660 may control a state of each of the switches M₄, M₅, and M₆ of the die 615. In this regard, the control circuits 655 and 660 may include drivers (e.g., gate drivers), level shifters, and logic for controlling the drivers and the level shifters. Although the control circuits 655 and 660 are each shown as a single block/component on the die 610 and 615, respectively, the control circuits 655 and 660 may include/represent components distributed throughout the die 610 and 615, respectively, including those components for controlling the state of the switches M₁ through M₆. It is noted that, while circuitry associated with controlling (e.g., driving) the state of the switches M₁ through M₆ are generally in proximity to the switches M₁ through M₆, the control circuit 655 may include circuitry associated with controlling operation of other components (e.g., non-switch components not shown in FIGS. 6A and 6B) of the die 615 and/or the control circuit 660 may include circuitry associated with controlling operation of other components of the die 610. In some cases, certain components, such as clock circuits and bandgap voltage reference circuits, may be included in one of the control circuit 655 or 660. As one example, clock circuits may be consolidated in the control circuit 655, bandgap voltage reference circuits may be consolidated in the control circuit 660, or vice versa. As another example, clock circuits and/or bandgap voltage reference circuits may be distributed across both the control circuits 655 and 660.

Although FIGS. 5A-5B and 6A-6B provide examples of packages for implementing a portion of a power converter, various combinations and/or variations of these examples may also provide a package appropriate for implementing a portion of a power converter and thus are in accordance with one or more embodiments of the present disclosure. As one example, the package 505 of FIGS. 5A and 5B may be implemented with one or more openings (e.g., similar to the opening 645 of FIG. 6A) for thermal relief and/or with multiple die (e.g., similar to the die 610 and 615 of FIGS. 6A and 6B). As another example, the package 605 of FIGS. 6A and 6B may be formed without any opening and/or with a single die. Additional examples of packages and/or variations thereto are further described herein.

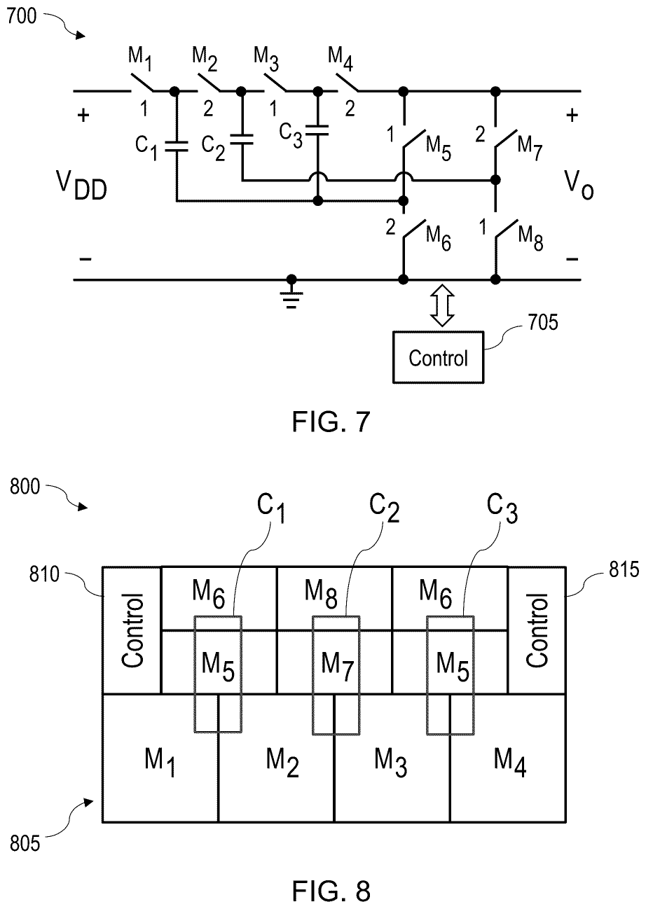

FIG. 7 illustrates a circuit diagram of an example power converter 700 in accordance with one or more embodiments of the present disclosure. Not all of the depicted components may be required, however, and one or more embodiments may include additional components not shown in the figure. Variations in the arrangement and type of the components may be made without departing from the spirit or scope of the claims as set forth herein. Additional, fewer, and/or different components may be provided. In some embodiments, an entirety of the power converter 700 may be implemented in a single package (e.g., a single QFN package). In other embodiments, a package may implement a portion of the power converter 700 and a remaining portion of the power converter 700 may be implemented using one or more additional packages and/or one or more discrete components external to the package.

The power converter 700 includes switches M₁ through M₈ and capacitors C₁ through C₃. In some embodiments, the switches M₁ through M₈ and the controller 705 may be integrated on one or more die within a package and the capacitors C₁ through C₃ may each be coupled to a respective set of switches on the die. In some embodiments, the power converter 700 may be, may include, or may be a part of the power converter 200 of FIG. 2, in which the switches M₁ through M₈ and the capacitors C₁ through C₃ may collectively implement the switched-capacitor circuit 225 and the controller 705 may implement the controller 220.

The switch M₁ is coupled to the switch M₂ and the capacitor C₁. The switch M₂ is coupled to the switches M₁ and M₃ and the capacitors C₁ and C₂. The switch M₃ is coupled to the switches M₂ and M₄ and the capacitors C₂ and C₃. The switch M₄ is coupled to the switches M₃, M₅, and M₇ and the capacitor C₃. The switch M₈ is coupled to the switches M₄, M₆, and M₇ and the capacitors C₁ and C₃. The switch M₆ is coupled to the switches M₅ and M₈ and the capacitors C₁ and C₃. The switch M₇ is coupled to the switches M₄, M₅, and M₈ and the capacitor C₂. The switch M₈ is coupled to the switches M₆ and M₇ and the capacitor C₂. In some aspects, the switches M₁ through M₈ are lateral switches. In other aspects, the switches M₁ through M₈ may include vertical switches or a combination of vertical and lateral switches. In some aspects, the switches M₁ through M₈ may be transistors (e.g., LDMOS FETs). In some cases, one or more of the switches M₁ through My may be a power switch (e.g., power FET).

The capacitor C₁ is coupled to the capacitor C₃, a node between the switches M₁ and M₂, and a node between the switches M₅ and M₆. The capacitor C₂ is coupled to a node between the switches M₂ and M₃ and a node between the switches M₇ and M₈. The capacitor C₃ is coupled to the capacitor C₁, a node between the switches M₃ and M₄, and a node between the switches M₅ and M₆. In some embodiments, the capacitors C₁, C₂, and C₃ may be MLCCs. In some cases, the capacitors C₁ through C₃ may be referred to as fly capacitors or flying capacitors.

The controller 705 controls a state (e.g., on state, off state) of each of the switches M₁ through M₈. In this regard, the controller 705 may include drivers (e.g., gate drivers for switches implemented using transistors), level shifters, and logic for controlling the drivers and the level shifters. Although the controller 705 is shown as a single block, the controller 705 may include/represent components distributed throughout the circuit diagram of the power converter 700, including those components for controlling the state of the switches M₁ through M₈.

In accordance with one or more embodiments, the power converter 700 may implement a charge pump. The power converter 700 receives a voltage V_{DD} as input and generates a voltage Vₒ as its output. The input voltage V_{DD} may be provided by a power supply, such as the power supply 120 of FIG. 1. The switches M₁, M₃, M₅, and M₈ may form one group of switches (e.g., group one as identified with an index/identifier 1 in FIG. 7) and switches M₂, M₄, M₆, and M₇ may form another group of switches (e.g., group two as identified with an index/identifier 2 in FIG. 7). The index/identifier of 1 and 2 is arbitrary and utilized for convenience in identifying the two groups of switches. In a first switch state, the controller 705 may control the switches M₁ through M₈ such that the group one switches M₁, M₃, M₅, and M₈ are closed and the group two switches M₂, M₄, M₆, and M₇ are open. In a second switch state following the first switch state, the controller 705 may control the switches M₁ through M₈ such that the group two switches M₂, M₄, M₆, and M₇ are closed and the switches M₁, M₃, M₅, and M₈ are open. In this regard, control signals generated by the controller 705 to effectuate the first switch state may be referred to as being complementary to control signals generated by the controller 705 to effectuate the second switch state. In some cases, a dead-time interval may be implemented between the first switch state and the second switch state (i.e., after the first switch state but before transitioning to the second switch state). During the dead-time interval, the controller 705 may control the switches M₁ through M₈ such that all the switches are open to ensure a clean transition between the two switch states. As such, the controller 705 may cycle the switches M₁ through M₈ through the first switch state, the dead-time interval, and the second switch state to deliver the voltage Vₒ as the output of the power converter 700.

FIG. 8 illustrates a top view 800 of an example layout of a package (e.g., a QFN package) for implementing a power converter (or portion thereof) in accordance with one or more embodiments of the present disclosure. Not all of the depicted components may be required, however, and one or more embodiments may include additional components not shown in the figure. Variations in the arrangement and type of the components may be made without departing from the spirit or scope of the claims as set forth herein. Additional, fewer, and/or different components may be provided.

The package may include an IC die 805, a leadframe, metal clips, attachment elements, capacitors C₁, C₂, and C₃, and a mold compound. It is noted that a corresponding side view of the package may be similar to the side view 500 of FIG. 5A or variation thereof. As an example variation of the side view 500, a side view of the package may show one or more openings formed in the mold compound to expose a top surface of at least a portion of the capacitor C₁, C₂, and/or C₃. As such, the description of FIG. 5A generally applies to the package associated with the top view 800.

In some embodiments, the package may implement an entirety of the power converter 700 of FIG. 7. The die 805 includes switches M₁ through M₈ and control circuits 810 and 815. In some aspects, the switches M₁ through M₈ are lateral switches. In other aspects, the switches M₁ through M₈ may include vertical switches or a combination of vertical and lateral switches. In some aspects, the switches M₁ through M₈ are transistors (e.g., FETs). As one example, the switches M₁ through M& may be LDMOS FETs.

One or more of the switches M₁ through M₈ may be a power switch (e.g., power FET). A power switch may be formed of numerous smaller switches connected in parallel. In some cases, power switches may facilitate/accommodate applications involving a large amount of current while avoiding overheating. As shown in FIG. 8, at least the switches M₅ and M₆ may be power switches. In this regard, the top view 800 of the layout shows two blocks representing the power switch M₅ and two blocks representing the power switch M₆. Each block representing the power switches M₅ and M₆ may include one or more switches. For example, the power switch M₅ adjacent to the control circuit 810 in the layout may represent/include a first switch (or first set of switches) of the power switch M₅ coupled to the capacitor C₁, whereas the power switch M₅ adjacent to the control circuit 815 in the layout may represent/include a second switch (or second set of switches) of the power switch M₅ coupled to the capacitor C₃. Since switches of a power switch are in parallel, the first switch of the power switch M₅ is in parallel with the second switch of the power switch M₅. Similarly, with further reference to this example, the power switch M₆ adjacent to the control circuit 810 may represent/include a first switch (or first set of switches) of the power switch M₆ coupled to the capacitor C₁, whereas the power switch M₆ adjacent to the control circuit 815 may represent/include a second switch (or second set of switches) of the power switch M₆ coupled to the capacitor C₃. The first switch of the power switch M₆ is in parallel with the second switch of the power switch M₆.

The capacitors C₁, C₂, and C₃ are each coupled (e.g., via metal clips) to a respective subset of the switches implemented on the die 805. As shown in FIG. 8, the capacitors C₁, C₂, and C₃ are each arranged such that they are directly above the switches to which they are electrically connected. In this regard, the capacitor C₁ is directly above M₁, M₂, M₅, and M₆; the capacitor C₂ is directly above M₂, M₃, M₇, and M₈; and the capacitor C₃ is directly above M₃, M₄, M₅, and M₆. In some embodiments, the capacitors C₁, C₂, and C₃ are MLCCs. In some aspects, MLCCs may be used to provide higher capacitor density and/or voltage rating relative to other capacitor types, such as integrated capacitors (e.g., planar capacitors, trench capacitors). In some cases, the capacitors C₁, C₂, and C₃ may be referred to as fly capacitors or flying capacitors.

Each of the control circuits 810 and 815 may control a state of one or more of the switches M₁ through M₈. In this regard, the control circuits 810 and 815 may include drivers (e.g., gate drivers), level shifters, and logic for controlling the drivers and the level shifters. Although the control circuits 810 and 815 are shown as two discrete components positioned along substantially opposite edges of the die 805, the control circuits 810 and/or 815 may include/represent components distributed throughout the die 805, including those components for controlling the state of the switches M₁ through M₈. In general, for a given driver (e.g., gate driver), the driver is generally disposed in proximity to the switch whose state is controlled by the driver. With regard to power switches, including at least the switches M₅ and M₆, each individual switch of these power switches may be disposed in proximity to a driver to control the individual switch's state.

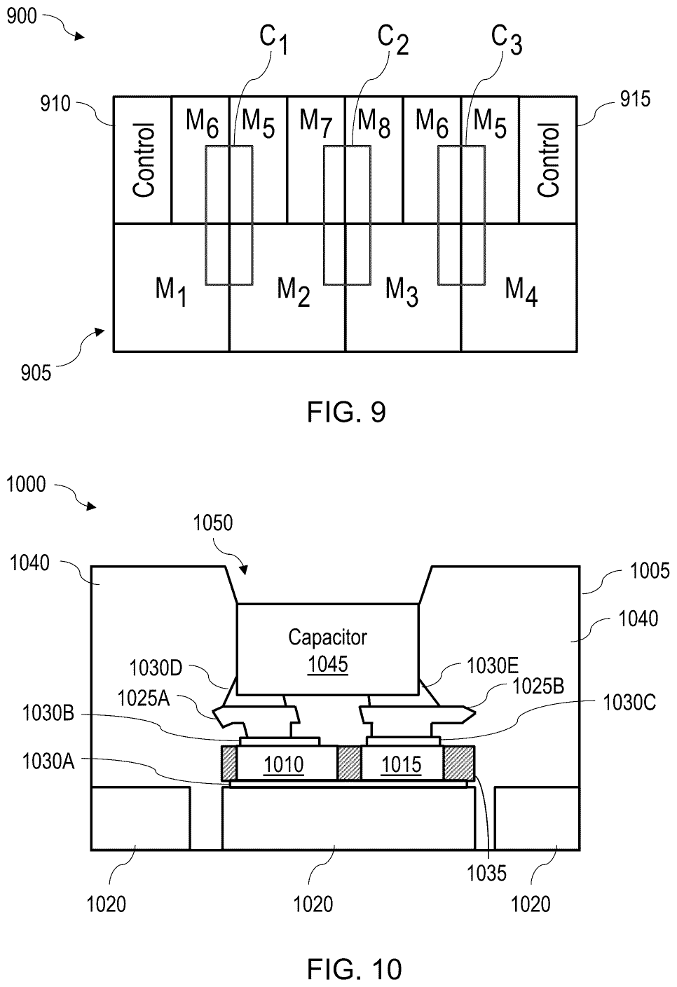

FIG. 9 illustrates a top view 900 of another example layout of a package for implementing a power converter (or portion thereof) in accordance with one or more embodiments of the present disclosure. Not all of the depicted components may be required, however, and one or more embodiments may include additional components not shown in the figure. Variations in the arrangement and type of the components may be made without departing from the spirit or scope of the claims as set forth herein. Additional, fewer, and/or different components may be provided. The description of FIG. 8 generally applies to FIG. 9, with examples of differences between FIGS. 8 and 9 and other description provided herein. In some cases, FIG. 9 provides an alternative layout for implementing the same power converter implemented by FIG. 8.

The package may include an IC die 905, a leadframe, metal clips, attachment elements, capacitors C₁, C₂, and C₃, and a mold compound. It is noted that a corresponding side view of the package may be similar to the side view 500 of FIG. 5A or variation thereof. As an example variation of the side view 500, a side view of the package may show one or more openings formed in the mold compound to expose a top surface of at least a portion of the capacitor C₁, C₂, and/or C₃. As such, the description of FIG. 5A generally applies to the package associated with the top view 900.

In some embodiments, the package may implement an entirety of the power converter 700 of FIG. 7. The die 905 includes switches M₁ through M₈ and control circuits 910 and 915. In an embodiment, at least the switches M₅ and M₆ are power switches (e.g., power FETs). In this regard, as shown in FIG. 9, the top view 900 of the layout shows two blocks representing the power switch M₅ and two blocks representing the power switch M₆.

The capacitors C₁, C₂, and C₃ are each coupled (e.g., via metal clips) to a respective subset of the switches implemented on the die 905. As shown in FIG. 9, the capacitors C₁, C₂, and C₃ are each arranged such that they are directly above the switches to which they are electrically connected. In this regard, as also described above with respect to FIG. 8, the capacitor C₁ is directly above M₁, M₂, M₅, and M₆; the capacitor C₂ is directly above M₂, M₃, M₇, and M₈; and the capacitor C₃ is directly above M₃, M₄, M₅, and M₆. In some embodiments, the capacitors C₁, C₂, and C₃ are MLCCs.

Each of the control circuits 910 and 915 may control a state of one or more of the switches M₁ through M₈. In this regard, the control circuits 910 and 915 may include drivers (e.g., gate drivers), level shifters, and logic for controlling the drivers and the level shifters. Although the control circuits 910 and 915 are shown as two discrete components positioned along substantially opposite edges of the die 905, the control circuits 910 and/or 915 may include/represent components distributed throughout the die 905, including those components for controlling the state of the switches M₁ through M₈. In general, for a given driver, the driver is generally disposed in proximity to the switch whose state is controlled by the driver. With regard to power switches, including at least the switches M₈ and M₆, each individual switch of these power switches may be disposed in proximity to a driver to control the individual switch's state.

For some manufacturing/assembling processes, the layout of FIG. 9 may be associated with easier defining/placement of the switches (e.g., M₅ through M₈) than the layout of FIG. 8. Furthermore, although FIGS. 8 and 9 show two example layouts of packages in which a power converter (e.g., a charge pump) is implemented using a single die, the packages may be implemented using two or more die (e.g., with switches and control circuits distributed across the multiple die).

FIG. 10 illustrates a side view 1000 of another example package 1005 for implementing a power converter (or portion thereof) in accordance with one or more embodiments of the present disclosure. Not all of the depicted components may be required, however, and one or more embodiments may include additional components not shown in the figure. Variations in the arrangement and type of the components may be made without departing from the spirit or scope of the claims as set forth herein. Additional, fewer, and/or different components may be provided. The description of FIGS. 5A and 6A generally apply to FIG. 10, with examples of differences between FIGS. 5A and 6A and FIG. 10 and other description provided herein. In some embodiments, the package 1005 may be used to implement the power converter 400 (or portion thereof) of FIG. 4, the power converter 700 (or portion thereof) of FIG. 7, and/or other power converter.

The package 1005 includes IC die 1010 and 1015, a leadframe 1020, metal clips 1025A and 1025B, attachment elements 1030A-E, a capacitor 1045 (e.g., MLCC), and mold compounds 1035 and 1040. In some cases, the package 1005 may include one or more additional capacitors, metal clips, attachment elements, and/or other components. The die 1010 and 1015 are attached to the leadframe 1020 via the attachment element 1030A. The metal clip 1025A is attached to the dic 1010 via the attachment element 1030B. The metal clip 1025B is attached to the die 1015 via the attachment element 1030C. The capacitor 1045 is attached to the metal clip 1025A via the attachment element 1030D and attached to the metal clip 1025B via the attachment element 1030E.

The metal clip 1025A connects the capacitor 1045 to the die 1010. The metal clip 1025B connects the capacitor 1045 to the die 1015. In some embodiments, at least some metal clips (e.g., the metal clips 1025A and 1025B) may be used primarily or even exclusively to connect capacitors (e.g., the capacitor 1045) to die (e.g., the die 1015 and/or 1015) and are not used to communicate (e.g., propagate signals) outside of a package. As such, these metal clips may, but need not, extend to a leadframe. As shown in the package 1005, the metal clips 1025A and 1025B do not extend to the leadframe 1020. In some cases, the metal clips 1025A and 1025B may be referred to as metal studs used to electrically connect the capacitor 1045 to the die 1010 and 1015, respectively. It is noted that, with reference for example to FIG. 6A, the metal clips 625A and 625B may be extended to the leadframe 620 to provide thermal paths for thermal relief even if the metal clips 625A and 625B do not necessarily need to form electrical connections with the leadframe 620.

The mold compound 1035 is disposed between and around the die 1010 and 1015 while leaving a bottom surface and a top surface of the die 1010 and 1015 exposed. In some aspects, the die 1010 and 1015 may be reconstituted die, although other techniques may be used to form the die 1010 and 1015. The mold compound 1040 encapsulates the die 1010 and 1015, the leadframe 1020, the metal clips 1025A and 1025B, the attachment elements 1030A-D, the mold compound 1035, and any additional component (if any) of the package 1005 not explicitly shown in FIG. 10. The mold compound 1035 and the mold compound 1040 may be formed of the same or different material.

The package 1005 has an (optional) opening 1050 defined therein to expose a top surface of at least a portion of the capacitor 1045. The opening 1050 may provide a thermal path for providing thermal relief for the package 1005. In some cases, the package 1005 may include one or more additional openings to provide one or more additional thermal paths. In some cases, one or more heat sinks (not shown) may be coupled to exposed top surfaces of capacitors (e.g., to further facilitate thermal relief). For example, a heat sink may be positioned within the opening 1050 to contact the capacitor 1045.

The die 1010 and 1015 may each include one or more switches (e.g., transistors, including power transistors in some cases) and one or more control circuits. The switches may be lateral switches and/or vertical switches. The capacitor 1045 is coupled to at least a subset of the switches implemented on the die 1010 and/or 1015. The capacitor 1045 may be arranged such that it is directly above the switches to which it is electrically connected.

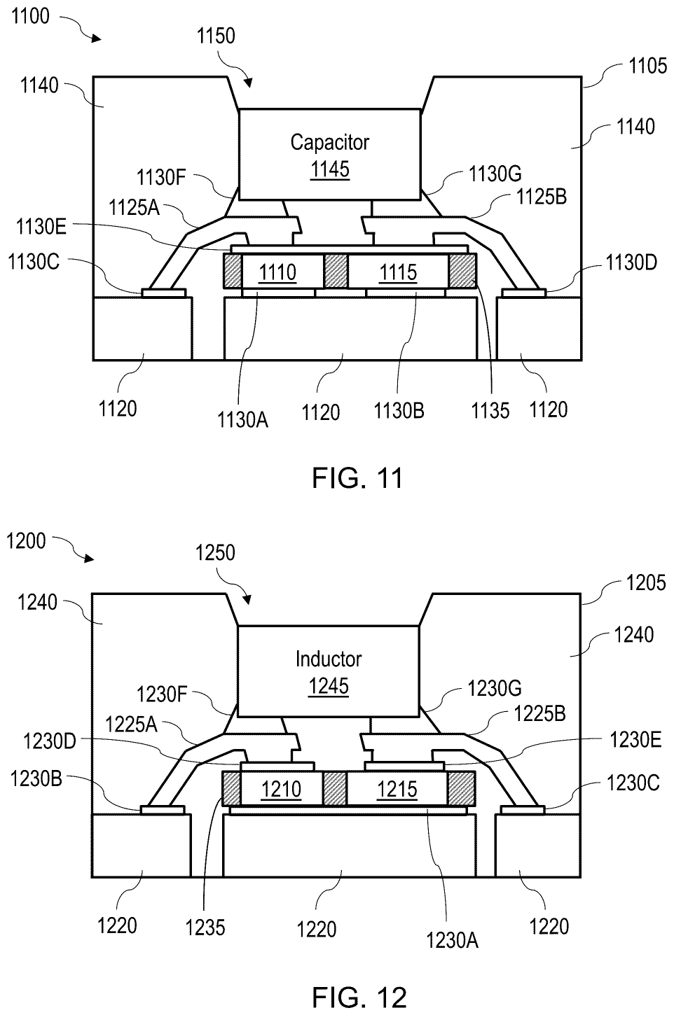

FIG. 11 illustrates a side view 1100 of another example package 1105 for implementing a power converter (or portion thereof) in accordance with one or more embodiments of the present disclosure. Not all of the depicted components may be required, however, and one or more embodiments may include additional components not shown in the figure. Variations in the arrangement and type of the components may be made without departing from the spirit or scope of the claims as set forth herein. Additional, fewer, and/or different components may be provided. The description of FIG. 10 generally applies to FIG. 11, with examples of differences between FIGS. 10 and 11 and other description provided herein. In some embodiments, the package 1105 may be used to implement the power converter 400 (or portion thereof) of FIG. 4, the power converter 700 (or portion thereof) of FIG. 7, and/or other power converter.

The package 1105 includes IC die 1110 and 1115, a leadframe 1120, metal clips 1125A and 1125B, attachment elements 1130A-G, a capacitor 1145 (e.g., MLCC), and mold compounds 1135 and 1140. In some cases, the package 1105 may include one or more additional capacitors, metal clips, attachment elements, and/or other components. The die 1110 and 1115 are attached to the leadframe 1120 via the attachment elements 1130A and 1130B, respectively. The metal clip 1125A is attached to the leadframe 1120 via the attachment element 1030C and attached to the die 1110 via the attachment element 1130E. The metal clip 1125B is attached to the leadframe 1120 via the attachment element 1130D and attached to the die 1115 via the attachment element 1130E. The capacitor 1145 is attached to the metal clip 1125A via the attachment element 1130F and attached to the metal clip 1125B via the attachment element 1130G. In some cases, the metal clip 1120A and/or the metal clip 1120B does not attach to the leadframe 1120.

Compared to the side view 1000 of FIG. 10, the die 1110 and 1115 are flipped relative to the die 1010 and 1015. In this regard, a front surface of the die 1110 and 1115 faces the leadframe 1120 and is coupled to the leadframe 1120 via the attachment elements 1130A and 1130B (e.g., solder bumps), and a back surface of the die 1110 and 1115 opposite the front surface is coupled to the metal clips 1125A and 1125B via the attachment element 1130E. The die 1110 and 1115 may be referred to as being flip-chip bonded to the leadframe 1120. In some aspects, with the die 1110 and 1115 flip-chip bonded to the leadframe 1120, thermal paths (e.g., for thermal relief) may be provided by the back surface of the die 1110 and 1115, while electrical connections may be provided from the front surface of the die 1110 and 1115 to the leadframe 1120 via the attachment elements 1130A and 1130B.

The metal clip 1125A connects the capacitor 1145 to the die 1110. The metal clip 1125B connects the capacitor 1145 to the die 1115. The mold compound 1135 is disposed between and around the die 1110 and 1115 while leaving the back surface and the front surface of the die 1110 and 1115 exposed. In some aspects, the die 1110 and 1115 may be reconstituted die, although other techniques may be used to form the die 1110 and 1115. The mold compound 1040 encapsulates the die 1110 and 1115, the leadframe 1120, the metal clips 1125A and 1125B, the attachment elements 1130A-G, the mold compound 1135, and any additional component (if any) of the package 1105 not explicitly shown in FIG. 11. The mold compound 1135 and the mold compound 1140 may be formed of the same or different material.

The package 1005 has an (optional) opening 1150 defined therein to expose a top surface of at least a portion of the capacitor 1145. The opening 1150 may provide a thermal path for providing thermal relief for the package 1105. In some cases, the package 1105 may include one or more additional openings to provide one or more additional thermal paths. In some cases, one or more heat sinks (not shown) may be coupled to exposed top surfaces of capacitors (e.g., to further facilitate thermal relief).

The die 1110 and 1115 may each include one or more switches (e.g., transistors, including power transistors in some cases) and one or more control circuits. The switches may be lateral switches and/or vertical switches. The capacitor 1145 is coupled to at least a subset of the switches implemented on the die 1110 and/or 1115. The capacitor 1145 may be arranged such that it is directly above the switches to which it is electrically connected.

Although the foregoing describes packages with capacitors, packages may include inductors alternatively or in addition to capacitors. As one example, FIG. 12 illustrates a side view 1200 of an example package 1205 with an inductor 1245 for implementing a power converter (or portion thereof) in accordance with one or more embodiments of the present disclosure. The description of FIG. 6A generally applies to FIG. 12, with examples of differences between FIGS. 6A and 12 and other description provided herein. Compared to FIG. 6A, the capacitor C₁ of FIG. 6A is replaced with the inductor 1245.

The package 1205 includes IC die 1210 and 1215 (e.g., reconstituted multiple die), a leadframe 1220, metal clips 1225A and 1225B, attachment elements 1230A-G, the inductor 1245, and mold compounds 1235 and 1240. In some cases, the package 1205 may include one or more capacitors, one or more additional inductors, one or more additional metal clips, one or more additional attachment elements, and/or other components. In some embodiments, the package 1205 may be a QFN package.

The die 1210 and 1215 are attached to the leadframe 1220 via the attachment element 1230A. The metal clip 1225A is attached to the leadframe 1220 via the attachment element 1230B and attached to the die 1210 via the attachment element 1230D. The metal clip 1225B is attached to the leadframe 1220 via the attachment element 1230C and attached to the die 1215 via the attachment element 1230E. The inductor 1245 is attached to the metal clip 1225A via the attachment element 1230F and attached to the metal clip 1225B via the attachment element 1230G. In some cases, the metal clip 1220A and/or the metal clip 1220B does not attach to the leadframe 1220.

The metal clips 1225A and 1225B connect the inductor 1245 to the die 1210 and 1215, respectively. The mold compound 1235 is disposed between and around the die 1210 and 1215 while leaving a back surface and a front surface of the die 1210 and 1215 exposed. The mold compound 1240 encapsulates the die 1210 and 1215, the leadframe 1220, the metal clips 1225A and 1225B, the attachment elements 1230A-G, the mold compound 1235, and any additional component (if any) of the package 1205 not explicitly shown in FIG. 12. The mold compound 1235 and the mold compound 1240 may be formed of the same or different material.

The package 1205 has an (optional) opening 1250 defined therein to expose a top surface of at least a portion of the inductor 1245. The opening 1250 may provide a thermal path for providing thermal relief for the package 1205. In some cases, the package 1205 may include one or more additional openings to provide one or more additional thermal paths. In some cases, one or more heat sinks (not shown) may be coupled to exposed top surfaces of inductors and/or capacitors (e.g., to further facilitate thermal relief).

The die 1210 and 1215 may each include one or more switches (e.g., transistors, including power transistors in some cases) and one or more control circuits. The switches may be lateral switches and/or vertical switches. The inductor 1245 may be coupled to at least a subset of the switches implemented on the die 1210 and/or 1215. In some cases, the inductor 1245 may be arranged such that it is directly above the switches to which it is electrically connected. Placement/coupling of the inductor 1245 directly above the switches may shorten the distance currents need to flow between the inductor 1245 and the die 1210 and 1215 relative to a case the inductor 1245 is not directly above their respective switches and a routing circuit is used to appropriate route signals between the inductor 1245 and their respective switches. In other cases, the inductor 1245 is not directly above the switches, in which the inductor 1245 and the switches may be appropriately routed via a routing circuit, which may provide flexibility in positioning of the inductor 1245 and/or the switches.

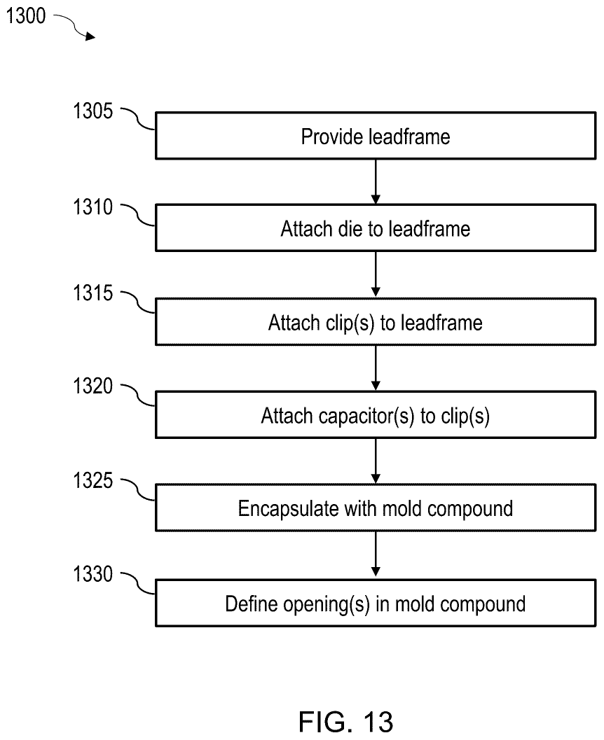

FIG. 13 illustrates a flow diagram of an example process 1300 of assembling a package for facilitating power conversion in accordance with one or more embodiment of the present disclosure. Any block of the process 1300 may be omitted from the process 1300 and/or other blocks may be included. For explanatory purposes, the process 1300 is described primarily with reference to the package 605 of FIGS. 6A and 6B. However, the process 1300 or a variation thereof may be performed to assemble the packages of other figures, variations of these packages, and/or other packages.

At block 1305, the leadframe 620 is provided. At block 1310, the die 610 and 615 are attached to the leadframe 620. The die 610 and 615 may be attached to the leadframe 620 via the attachment element 630A. For example, the die 610 and 615 may be soldered to the leadframe 620. In some cases, the die 610 and 615 may be reconstituted multiple die (e.g., reconstituted multiple silicon die) with the mold compound 635 disposed between and around the die 610 and 615. At block 1315, the metal clips 625A and 625B are attached to the die 610 and 615, respectively. The metal clip 625A may be attached to the die 610 via the attachment element 630D. The metal clip 625B may be attached to the die 615 via the attachment element 630E. For example, the metal clip 625A may be soldered to the die 610, and/or the metal clip 625B may be soldered to the die 615.

At block 1320, the capacitor C₁ is attached to the metal clips 625A and 625B. The capacitor C₁ may be attached to the metal clip 625A via the attachment element 630F and attached to the metal clip 625B via the attachment element 630G. For example, the capacitor C₁ may be soldered to the metal clips 625A and 625B. The capacitor C₂ may be similarly attached to the die 610 and 615. With reference to FIG. 6B, the capacitor C₁ is attached directly above the switches M₁, M₂, M₅, and M₆, and the capacitor C₂ is attached directly above the switches M₂, M₃, M₄, and M₅.

At block 1325, the mold compound 640 encapsulates the leadframe 620, the die 610 and 615, the metal clips 625A and 625B, the attachment elements 630A-G, and the capacitors C₁ and C₂. At block 1330, a portion of the mold compound 640 is removed to form the opening 645 to expose at least a portion of the capacitor C₁. In one aspect, to form the opening 645, a portion of a top surface of the mold compound 640 may be grinded downwards close to a top surface of the capacitor C₁ and then an acid applied to the mold compound 640 to remove the mold compound 640 on the top surface of the capacitor C₁ in order to expose the top surface of the capacitor C₁. In some cases, a heat sink (not shown) may be coupled to the exposed top surface of the capacitor C₁. In some cases, one or more additional openings may be formed in the mold compound 640 to expose at least a portion of the capacitor C₂ and/or other component. A heat sink may be coupled to one or more of the additional opening(s). In some aspects, block 1330 is optional. For example, the package 605 may be formed without the opening 645. In some embodiments, the package 605 has been assembled upon completion of block 1325 or 1330. In other embodiments, additional processing may be performed to arrive at the package 605.

Where applicable, various embodiments provided by the present disclosure can be implemented using hardware, software, or combinations of hardware and software. Also, where applicable, the various hardware components and/or software components set forth herein can be combined into composite components comprising software, hardware, and/or both without departing from the spirit of the present disclosure. Where applicable, the various hardware components and/or software components set forth herein can be separated into sub-components comprising software, hardware, or both without departing from the spirit of the present disclosure. In addition, where applicable, it is contemplated that software components can be implemented as hardware components, and vice-versa.

Software in accordance with the present disclosure, such as non-transitory instructions, program code, and/or data, can be stored on one or more non-transitory machine-readable mediums. It is also contemplated that software identified herein can be implemented using one or more general purpose or specific purpose computers and/or computer systems, networked and/or otherwise. Where applicable, the ordering of various steps described herein can be changed, combined into composite steps, and/or separated into sub-steps to provide features described herein.

Embodiments described above illustrate but do not limit the present disclosure. It should also be understood that numerous modifications and variations are possible in accordance with the principles of the present disclosure. Accordingly, the scope of the invention is defined only by the following claims.

1. A semiconductor package comprising:
a leadframe;
an integrated circuit (IC) die coupled to the leadframe, wherein the IC die comprises
a plurality of switches coupled in series between an input voltage and a ground reference;
a plurality of metal clips;
at least one energy storage component coupled to the IC die via the plurality of metal clips, wherein each of the at least one energy storage component is coupled to a respective subset of the plurality of switches via a respective subset of the plurality of metal clips; and
a mold compound to encapsulate the leadframe, the IC die, the plurality of metal clips, and the at least one energy storage component.

2. The semiconductor package of claim 1, wherein the IC die is a first IC die and the plurality of switches is a first plurality of switches, wherein the first IC die further comprises a first control circuit configured to control a state of at least a subset of switches of the plurality of switches, wherein the semiconductor package further comprises:
a second IC die coupled to the leadframe, wherein the second IC die comprises a second plurality of switches and a second control circuit, and wherein the at least one energy storage component is coupled to at least one switch of the first plurality of switches and at least one switch of the second plurality of switches.

3. The semiconductor package of claim 2, wherein the first control circuit is configured to control a state of each switch of the first plurality of switches, and wherein the second control circuit is configured to control a state of each switch of the second plurality of switches.

4. The semiconductor package of claim 3, wherein the first control circuit comprises gate drivers and level shifters associated with controlling the state of each switch of the first plurality of switches, and wherein the second control circuit comprises gate drivers and level shifters associated with controlling the state of each switch of the second plurality of switches.

5. The semiconductor package of claim 2, wherein the first IC die is a first reconstituted die, and wherein the second IC die is a second reconstituted die.

6. The semiconductor package of claim 1, wherein the plurality of metal clips are coupled to the leadframe, and wherein the at least one energy storage component is coupled to the leadframe via the plurality of metal clips.

7. The semiconductor package of claim 1, wherein the IC die further comprises:
a first control circuit configured to control a state of a subset of the plurality of switches; and
a second control circuit configured to control a state of the remaining switches of the plurality of switches.

8. The semiconductor package of claim 1, wherein the plurality of switches comprises a plurality of lateral transistors.

9. The semiconductor package of claim 1, wherein a top surface of at least a portion of the at least one energy storage component is exposed to provide a thermal path.

10. The semiconductor package of claim 1, wherein the semiconductor package is a quad flat no-lead package, wherein the IC die further comprises a control circuit configured to control a state of at least a subset of switches of the plurality of switches, and wherein the at least one energy storage component comprises at least one multi-layer ceramic capacitor.

11. The semiconductor package of claim 1, wherein a front surface of the IC die faces the leadframe and is coupled to the leadframe via a plurality of solder bumps, and wherein a back surface of the IC die opposite the front surface is coupled to the plurality of metal clips.

12. The semiconductor package of claim 1, wherein the at least one energy storage component comprises a first energy storage component and a second energy storage component, wherein at least one switch of the plurality of switches comprises a power field-effect transistor (FET), wherein the power FET comprises a plurality of FETs, wherein a first FET of the plurality of FETs is coupled to the first energy storage component, wherein a second FET of the plurality of FETs is coupled to the second energy storage component, and wherein the first FET is in parallel with the second FET.

13. An electronic device comprising the semiconductor package of claim 1, the electronic device comprising:
a power converter comprising:
the semiconductor package; and
a capacitor coupled to and external to the semiconductor package.

14. A multi-level power converter comprising the semiconductor package of claim 1, the multi-level power converter further comprising:
an inductor coupled to at least two switches of the plurality of switches of the IC die via at least one of the plurality of metal clips.

15. A charge pump comprising the semiconductor package of claim 1, wherein the IC die further comprises a control circuit configured to control a state of each switch of the plurality of switches such that:
during a dead time state of the charge pump, each switch of the plurality of switches is in an off state;
during a first switch state of the charge pump, a first subset of the plurality of switches is in an on state and a second subset of the plurality of switches is in the off state; and
during a second switch state of the charge pump, the first subset of the plurality of switches is in the off state and the second subset of the plurality of switches is in the on state.

16. A method of assembling a semiconductor package, the method comprising:
providing a leadframe;
attaching an IC die to the leadframe, wherein the IC die comprises
a plurality of switches coupled in series between an input voltage and a ground reference;
attaching a plurality of metal clips to the IC die;
attaching at least one energy storage component to the plurality of metal clips such that each of the at least one energy storage component is coupled to a respective subset of the plurality of switches via a respective subset of the plurality of metal clips; and
encapsulating the leadframe, the IC die, the plurality of metal clips, and the at least one energy storage component with a mold compound.

17. The method of claim 16, further comprising:
attaching at least one of the plurality of metal clips to the leadframe; and
removing a portion of the mold compound to expose at least a portion of the at least one energy storage component.

18. The method of claim 16, wherein the IC die is a first IC die and the plurality of switches is a first plurality of switches, wherein the first IC die further comprises a first control circuit configured to control a state of at least a subset of the first plurality of switches, the method further comprising:
attaching a second IC die to the leadframe, wherein the second IC die comprises:
a second plurality of switches; and
a second control circuit configured to control a state of at least a subset of the second plurality of switches, wherein the at least one energy storage element is coupled to at least one switch of the first plurality of switches and at least one switch of the second plurality of switches.

19. The method of claim 18, wherein the first IC die is a first reconstituted die, and wherein the second IC die is a second reconstituted die.

20. The method of claim 16, wherein the plurality of switches comprises a plurality of lateral transistors.
